(19) United States
(12) Patent Application Publication
(10) Pub. No.: US 2008/0024136 A1
(43) Pub. Date: Jan. 31, 2008

(54) MEASURING PIXEL CURRENT IN DISPLAY DEVICE

(76) Inventors: Seiichi Mizukoshi, Kanagawa (JP); Makoto Kohno, Kanagawa (JP); Kouichi Onomura, Yokohama-shi (JP)

Correspondence Address: Frank Pincelli;Patent Legal Staff, Eastman Kodak Company, 343 State Street, Rochester, NY, 14650-2201, US

(21) Appl. No.: 11/775,263

(22) Filed: Jul. 10, 2007

(30) Foreign Application Priority Data
Jul. 26, 2006 (JP) 2006-202720

(51) Int. Cl. G01R 31/44

(52) U.S. Cl. 324/403

(57) ABSTRACT

Pixel current flowing in each pixel of a display panel is efficiently measured. The display panel 20 includes pixels arranged in a matrix, and performs display by writing pixel data in these pixels. By turning on one pixel alone within a screen for a period of a limited number of lines within one frame, a plurality of pixels are sequentially turned on within one frame. By measuring the current used for performing display within the period during which one pixel alone is turned on, pixel current that flows in that pixel is measured.

### CROSS-REFERENCE TO RELATED APPLICATION

This application claims priority of Japanese Patent Application No. 2006-202720 filed Jul. 26, 2006 which is incorporated herein by reference in its entirety.

### FIELD OF THE INVENTION

The present invention relates to a display device having pixels arranged in a matrix.

### BACKGROUND OF THE INVENTION

FIG. 1 shows a configuration of a circuit for one pixel (pixel circuit) in a basic, active organic EL display device. FIG. 2 shows the configuration of a display panel and input signals.

The pixel circuit is composed of an n-channel selection TFT 2, a p-channel driving TFT 1, a retention capacitance C, and an organic EL element. The selection TFT 2 is connected to a gate line Gate at the gate while it is connected to a data line Data at one end and to the gate of the driving TFT 1 at the other end. The driving TFT 1 is connected to a power supply line PVdd at the source and to the anode of the organic EL element at the drain, The cathode of the organic EL element is connected to a cathode power supply CV. The retention capacitance C connects the gate and the source of the driving TFT 1.

By applying a data signal having a voltage corresponding to the display luminance on the data line Data (extending in the vertical direction) while the gate line Gate (extending in the horizontal direction) is kept at the H level and the selection TFT 2 is kept turned on. The data signal is thereby accumulated in the retention capacitance C. This enables the driving TFT 1 to supply driving current corresponding to the data signal to the organic EL element for the organic EL element to emit light.

There is almost direct proportionality between an amount of light emission of the organic EL element and the current. Normally, by taking the threshold voltage Vth into account, voltage (Vth) is selected to allow drain current to start flowing near the black level of an image and is provided between the gate of the driving TFT 1 and the PVdd. In addition, specified luminance near the white level is provided as the amplitude of an image signal.

The data lines Data are connected to a source driver 22, and the source driver 22 performs an operation to sequentially distribute the image data signal inputted therein to the respective data lines Data according to the dot clock and the horizontal synchronization signal repetitively for each horizontal line. A gate driver 24 turns on a gate line Gate corresponding to the input image data signal according to the vertical synchronization signal and the horizontal synchronization signal inputted therein.

FIG. 3 shows a r CV current in which the current flows in the organic EL element, with respect to input signal voltage of the driving TFT 1 (voltage of the data line Data). By determining the data signal so that Vb is given as the black level voltage and Vw is given as the white level voltage, it is possible to perform appropriate grayscale control in the organic EL element. The CV current corresponds to the data voltage flows in the organic EL element.

The luminance when a pixel is driven at a given voltage varies with the Vth of the driving TFT 1, and it corresponds to signal voltage when an input voltage near the PVdd-Vth displays black. Likewise, the slope or inclination (μ) of the V-I curve of the TFT may vary, and in such a case, as is shown in FIG. 4, input amplitude (Vp-p) should vary to achieve the same luminance. Because the threshold voltage Vth(i) and the slope (μ) of a TFT(i) serving as the driving TFT 1 are smaller than those of a TFT(ii) also serving as the driving TFT 1, the input amplitude Vp-p(i) of the TFT(i) becomes larger than the input amplitude Vp-p(ii) of the TFT(ii).

When the Vth and the μ of the TFT within the display panel vary as described above, drain current for the same signal level varies, which gives rise to irregular luminance.

For the purpose of correcting such irregular luminance, the V-I curve of the individual TFT is found by measuring panel current that flows when each pixel is turned on at several signal levels as disclosed, for example, in U.S. Patent Application Publication 2004-150592 and WO 2005101260.

Meanwhile, in order to mitigate the afterimage phenomenon occurring when high luminance data set in an optical element is overwritten with low luminance data, an active-matrix organic EL display device has been developed, in which a period for writing black data into the TFT's is provided within one frame period as disclosed, for example, in JP-A-2003-208124, JP-A-2003-263129, and JP-A-2004-341241.

When a normal display panel driving method is used, the fastest measuring method is to turn on one pixel within one frame period and measure the current within this period. In this case, a time needed to measure the current for all the pixels is found to be the number of pixels×frame period. For example, in a case where a display panel formed of 960×240 pixels is driven at 60 frames/sec, it takes at least 960×240/60=3840 sec. Further, in order to check the slope of the V-I curve, it is necessary to measure the current by turning on a pixel at several signal levels. It therefore takes several times longer than the time specified above. This required time is impractical to measure pixel current periodically as the product for correcting a change of the TFT's with time. In a case where the pixel current is measured during fabrication for the purpose of correcting irregularities, the required time may possibly lower the production efficiency.

### SUMMARY OF THE INVENTION

One aspect of the invention is a display device that performs display by writing pixel data in each of pixels arranged in a matrix, wherein turning on one pixel alone within a screen and then turning off the pixel after measuring pixel current is performed a plurality of times within one frame, so as to obtain measurements of pixel current concerning a plurality of pixels within one frame period.

It is preferable that the display device turns off a pixel after a period of a pre-set number of lines since the data was written therein, and turns on one pixel alone for a period of one or more lines using the function.

Also, it is preferable that the display device is an organic EL display device in which an organic EL element is provided to each pixel.

Another aspect of the invention is a display device that performs display by writing pixel data in each of pixels arranged in a matrix, including: a turn-on portion that turns on one pixel alone within a screen; a current measurement portion that measures current flowing in the display device; and a turn-off portion that turns off the pixel after pixel current is measured, wherein measurements of pixel current concerning a plurality of pixels are obtained within one frame period by measuring current used for display in a period during which one pixel alone is turned on by the turn-on portion using the current measurement portion.

Also, it is preferable that the display device further includes a correction data memory that stores correction data to correct pixel data to be supplied to each pixel, and that the correction data is re-written by the pixel current measured.

According to the invention, by turning on and then turning off a plurality of pixels within one frame, it is possible to obtain measurements of pixel current concerning a plurality of pixels. It is therefore possible to shorten a time needed to measure the pixel current for all the pixels.

### BRIEF DESCRIPTION OF THE DRAWINGS

FIG. 1 is a view showing one example of a prior art pixel circuit;

FIG. 2 is a view showing the configuration of a display panel;

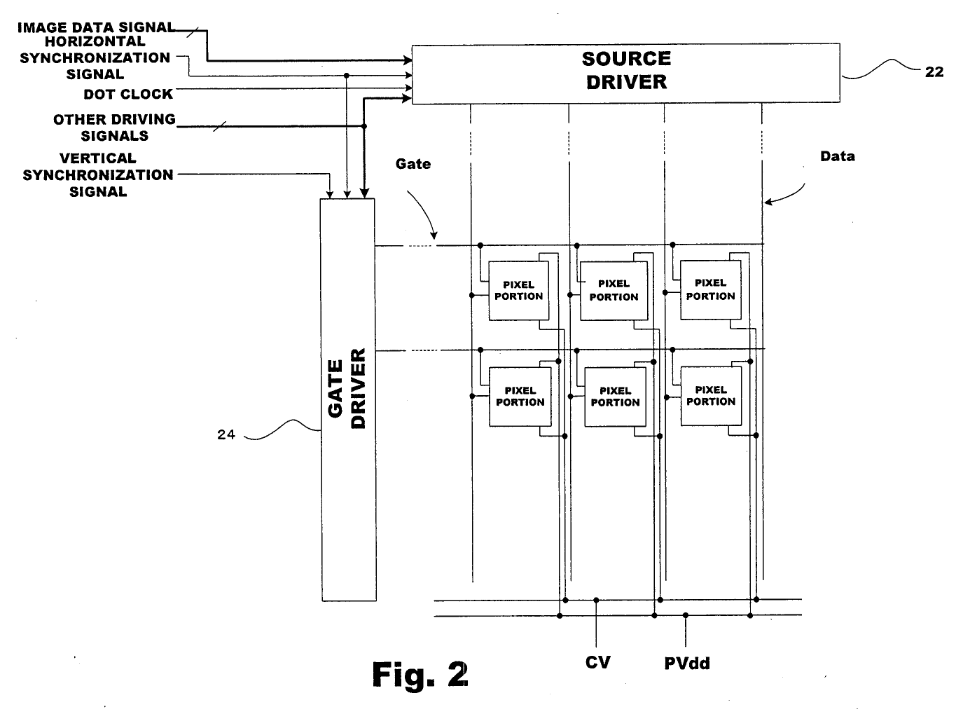

FIG. 3 is a view showing a relation of data voltage and CV current;

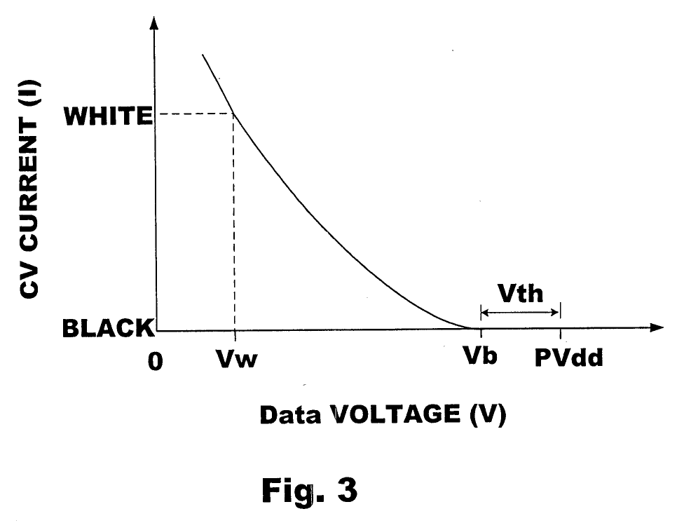

FIG. 4 is a view showing a relation of data voltage corresponding to the characteristic of a driving TFT and CV current;

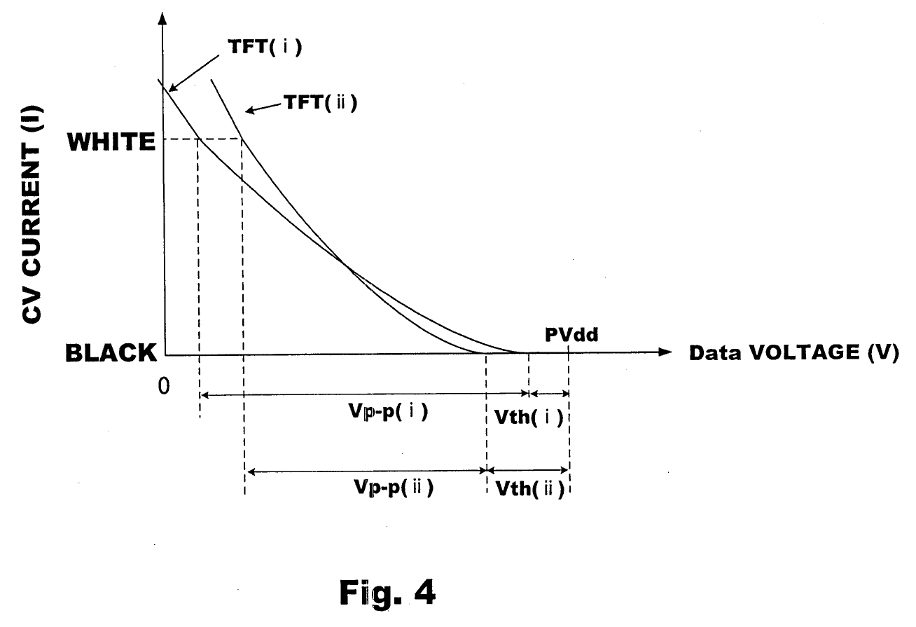

FIG. 5 is a view showing one example of a pixel circuit according to one embodiment of the invention;

FIG. 6 is a view showing the configuration of a display panel according to one embodiment of the invention;

FIG. 7 is a timing chart of signals to control turning-on and turning-off of each pixel;

FIG. 8 is a view used to describe a particular method for a pixel;

FIG. 9A is a view showing turning-on of pixels in frames 1 through 4;

FIG. 9B is a view showing turning-on of pixels in frames 5 through 8;

FIG. 9C is a view showing turning-on of pixels in frames (4M-3) through (4M);

FIG. 10 is a view showing a turn-on state of pixels in one column;

FIG. 11 is a view showing the configuration to obtain measurements of pixel current; and

FIG. 12 is a view showing a state of pixel current with time.

### DESCRIPTION OF THE PREFERRED EMBODIMENT

Hereinafter, one embodiment of the invention will be described with reference to the drawings.

In this embodiment, in an active-matrix organic EL display device furnished with the function of turning off a turned-on line after a period of a pre-set number of lines since the writing of data, the display panel is driven by a method different from the normal method when measurements of current pixel are obtained.

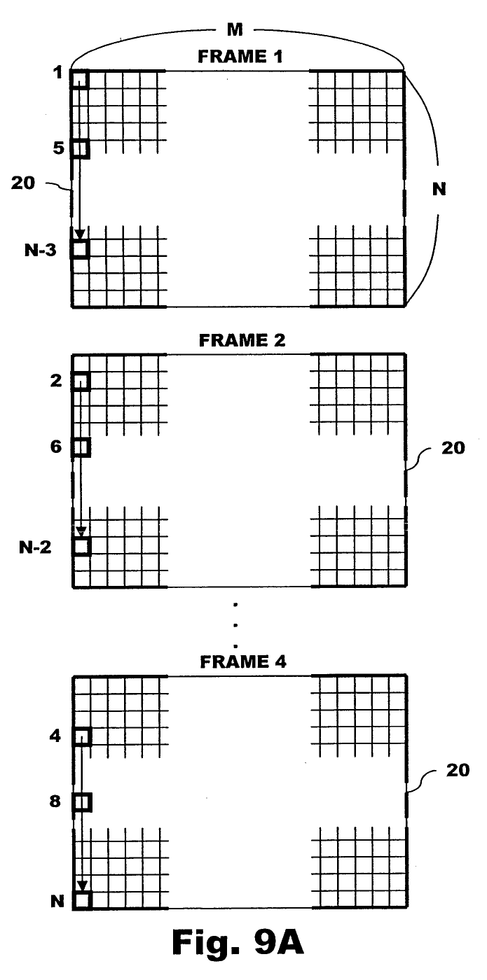

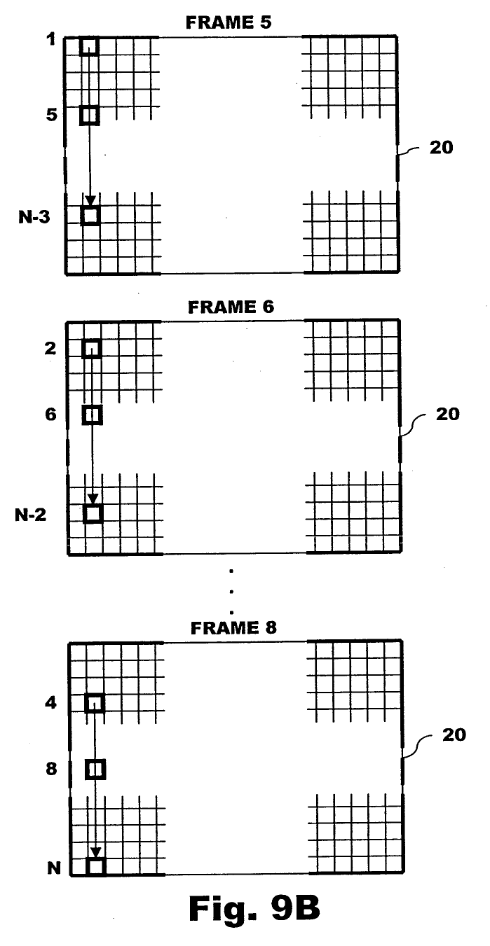

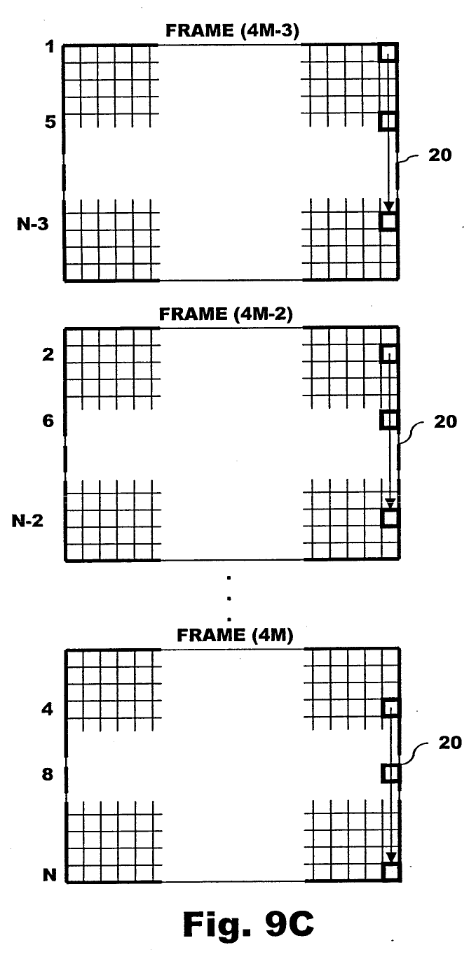

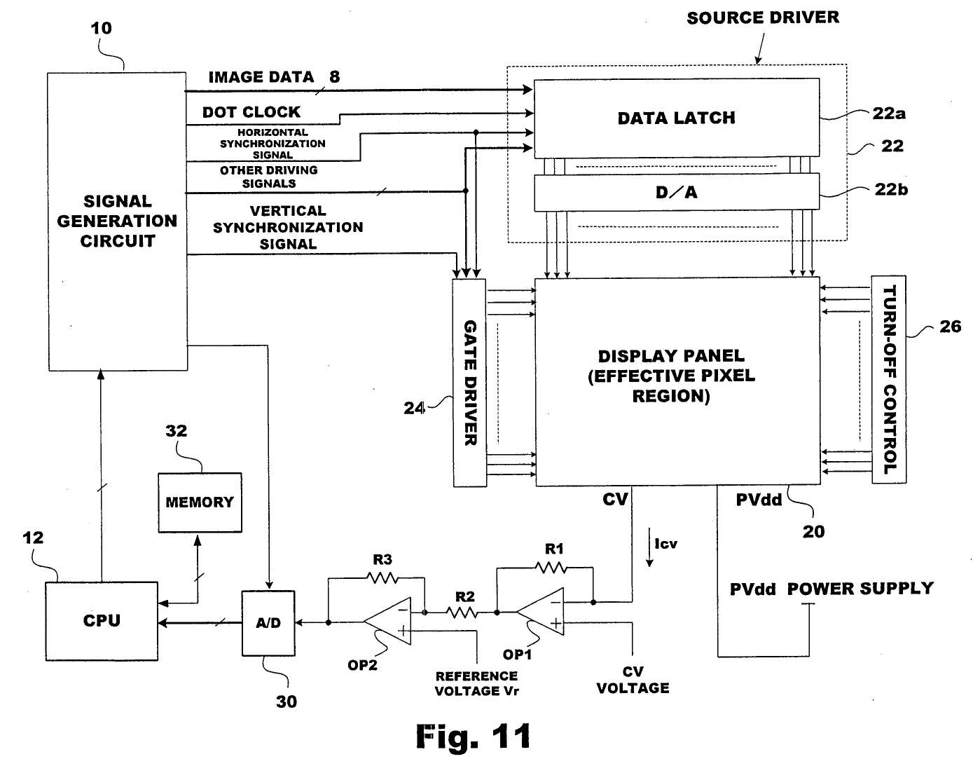

FIGS. 9A, 9B, and 9C show a manner in which pixels are turned on one by one using the aforementioned driving method. FIG. 11 shows one example of the circuit configuration to obtain measurements of pixel current.

A signal generation circuit 10 generates image data and a control signal to enable driving shown in FIGS. 9A through 9C according to an instruction from a CPU 12. Besides image data indicating the luminance level for each dot (normally, RGB color luminance signals), the dot clock corresponding to a data break of the image data for each dot, the horizontal synchronization signal indicating a break for one horizontal line's worth of image data, and the vertical synchronization signal indicating a break of one frame, a turn-off signal is included herein as other driving signals.

The display panel includes a display panel (effective pixel region) 20, a source driver 22, a gate driver 24, and a turn-off control 26. The source driver 22 includes a data latch 22a and a D/A converter 22b.

One horizontal line's worth of the image data per dot is stored in the data latch 22a, and a signal for each dot is converted to data of an analog voltage by the D/A converter 22b to be put on the data line Data according to the horizontal synchronization signal. Also, the gate driver 24 sequentially moves a gate line that is activated according to the horizontal synchronization signal. Data is thus written into the pixels sequentially. The turn-off control 26 performs a turn-off operation for a horizontal line in which the data has been written by erasing the written data after a lapse of a period of a specified number of horizontal lines (for example, four lines).

The CV terminal of the display panel is connected to the minus input of an operational amplifier OP1, and a cathode power supply CV is connected to the plus terminal thereof for CV voltage to be supplied thereto. The minus input and the output of the operational amplifier OP1 are connected via a register R1. The output of the operational amplifier OP1 is connected to the minus input of an operational amplifier OP2 via a register R2. Reference voltage Vr is inputted into the plus input of the operational amplifier OP2, and the minus input and the output thereof are connected via a register R3.

The output of the operational amplifier OP2 is connected to the CPU 12 via an A/D converter 30, so that an output from the operational amplifier OP2 is supplied to the CPU 12 as digital data. A memory 32 is connected to the CPU 12.

According to the configuration described above, voltage found to be (CV voltage−Icv×R1) is outputted to the output terminal of the operational amplifier OP1. Herein, Icv is the current flowing in the cathode power supply CV from the display panel, and it is the current that flows in one dot when this dot alone is turned on. The operational amplifier OP2 is to adjust offset voltage and amplitude at the output of the operational amplifier OP1, and the registers R2 and R3 and the reference voltage Vr are set so that an output from the operational amplifier OP2 achieves the most appropriate amplitude and offset voltage to be inputted into the A/D converter 30.

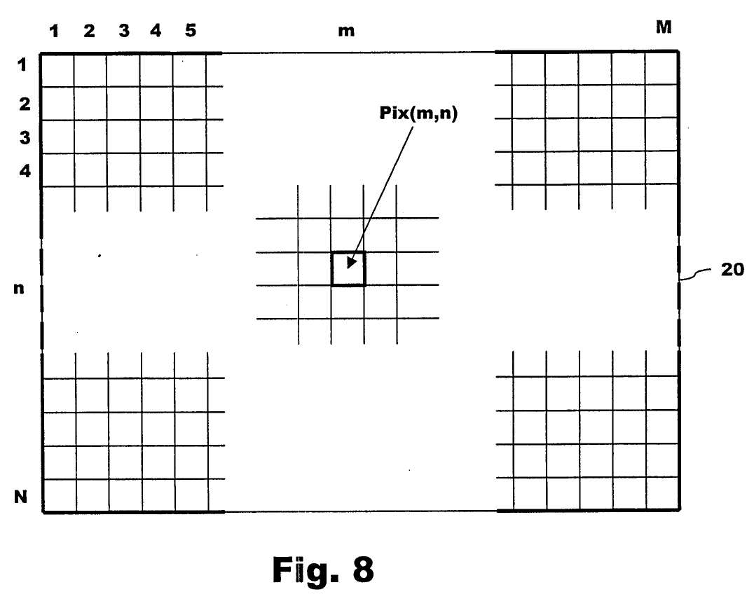

The turn-on control of each pixel will now be described. The position of each pixel on the display panel with m columns and n rows is given as a pixel position, pix(m, n), as is shown in FIG. 8.

As is shown in FIG. 9A, pix(1, 1) is turned on first. Subsequently, pix(1, 5) is turned on and at the same time pix(1, 1) is turned off by turning off a line 1. Thereafter, turning-on and turning off are repeated sequentially for pix(1, 9), pix(1, 13), and pix(1, 17). Accordingly, ¼ of pixels in one column are turned on individually for a period of four horizontal lines (a period of lines) within one frame.

In this manner, all the pixels in one column are turned on for a period of four horizontal lines in four frames. The current Icv is measured for each pixel in this instance.

After pix(1, N-3) is turned on (turning on and turning off in four frames), as is shown in FIG. 9B, the turning on and the turning off are repeated in a downward direction for every four dots from pix(2, 1) in the following column in the same manner as above. In short, when the measurements of current for all the pixels in the first column end in four frames, the measurements are performed in the same manner for the second column. The measurements of current for all the pixels end when the measurements as above are repeated to the M'th column as is shown in FIG. 9C. In FIGS. 9A through 9C, by inputting image data that allows pixels indicated by white rectangles to turn on, these pixels are turned on sequentially as described above, and it is always one pixel alone that is turned on.

In this case, a particular column is turned on within each frame. However, the position of a pixel to be turned on can be arbitrary as long as turning-on is performed for each pre-set horizontal line.

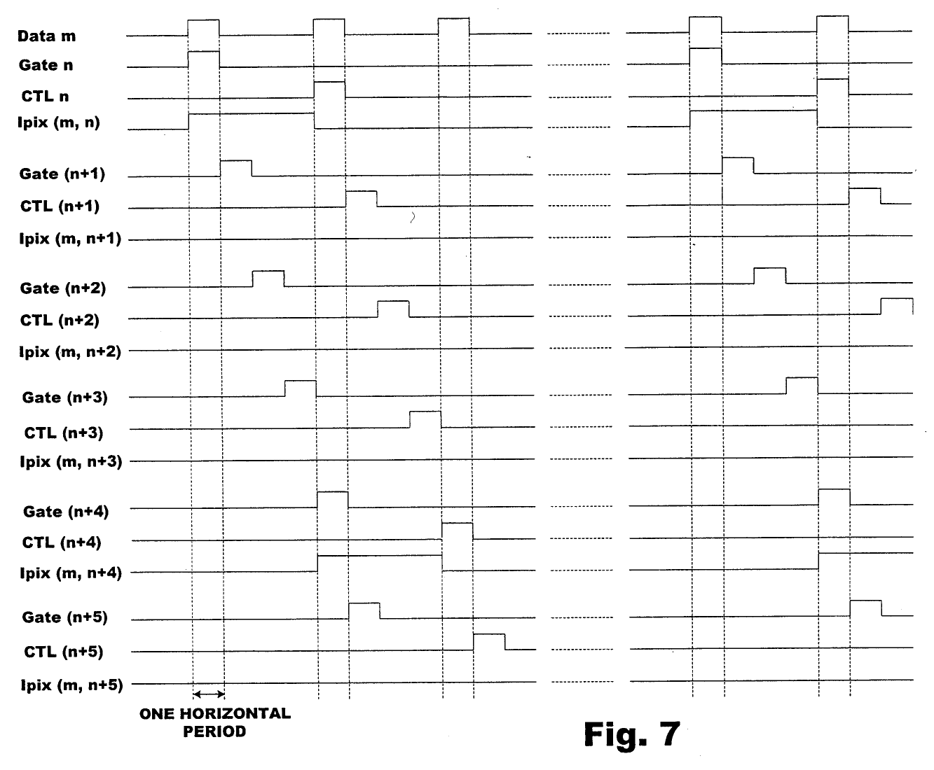

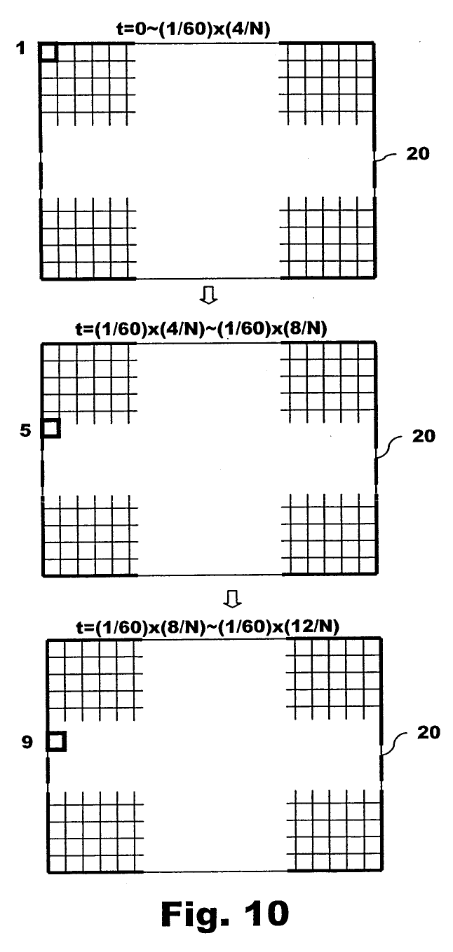

FIG. 7 shows a relation of the timing of the gate line Gate and a control line CTL and current Ipix flowing in the pixel. FIG. 10 shows turn-on periods of each of the pixels at pix(1, 1), pix(1, 5), and pix(1, 9). This is a case where current flowing in pixels in one column is measured in four frames as described above; however, the number of frames is not particularly limited to four.

According to this method, when one frame period is 1/60 sec, a time T needed to measure all the pixels is found to be T=(1/60)×4M=M/15 (sec). For example, in a case where a display panel formed of 960×240 pixels is driven at 60 frames/sec, 960/15=64 sec is needed. It is therefore possible to shorten the measuring time markedly in comparison with a case where the current is measured for one pixel within one frame.

In addition, in this method, a time needed for the writing in pixels is the same as in the normal driving. Hence, there is an advantage that neither a particular driving pulse has to be generated nor a particular circuit has to be additionally provided to obtain measurements of current.

In this case, one pixel is turned on for a period of four lines. However, a period of how many lines the pixel is turned on for can be determined arbitrarily. The measuring time can be shortened by making the turn-on period shorter. However, it is normal for it to take a time until the pixel current is stabilized, and a time needed for stabilization depends on the characteristic of the display panel. It is therefore suitable to set a period of line(s) to match the characteristic of the display panel in such a manner that the current flows in a pixel for a period as short as possible within a period during which the pixel current stays stable.

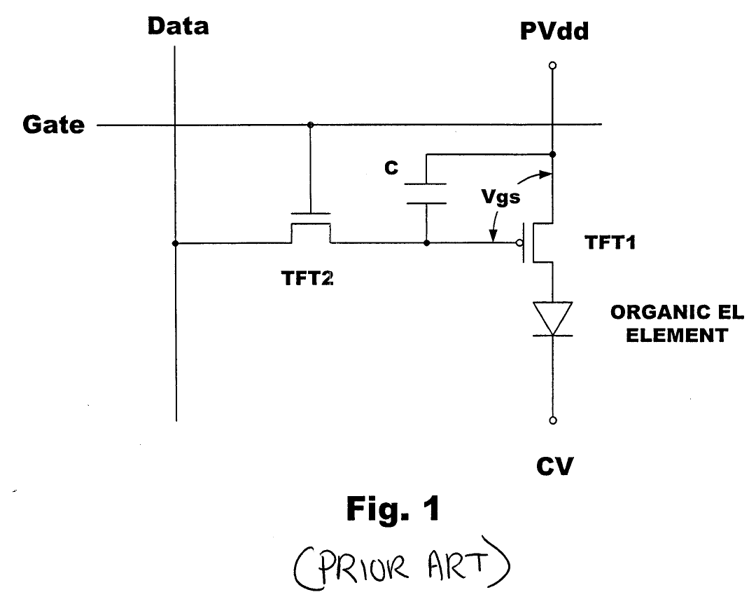

For one example of the pixel circuit of FIG. 1, a distribution constant circuit by means of wire resistance, a stray capacitance, and the like is present for each power supply line and signal line in practice. Hence, in a case where the PVdd or the CV current is measured from the outside, the measured current increases gradually. It is therefore necessary to measure the current when the current has stabilized.

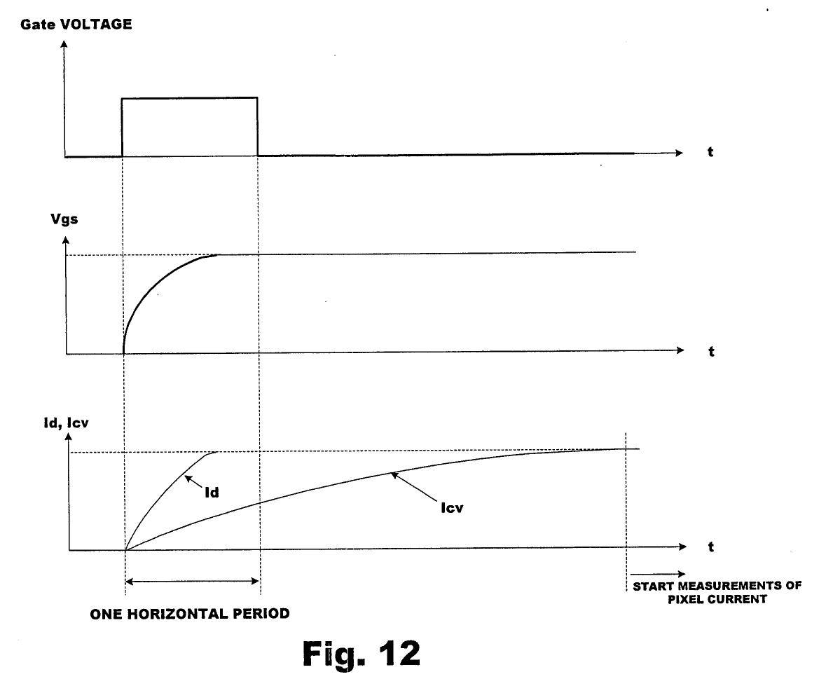

FIG. 12 shows one example of a relation of the current flowing in an organic EL element and the CV current. As is shown therein, in a case where the gate line Gate has shifted to the H level during a period of one horizontal line, the voltage Vgs between the gate and source of the driving TFT 1 increases gradually and eventually reaches the voltage corresponding to the data within a period of one horizontal line. Meanwhile, the drain current Id of the driving TFT 1 reaches the corresponding current value within a period of one horizontal line. However, the CV current Icv, which is an output from the display panel to be actually measured, fails to reach the current value corresponding to the drain current Id within a period of one horizontal line and a period of several horizontal lines are required.

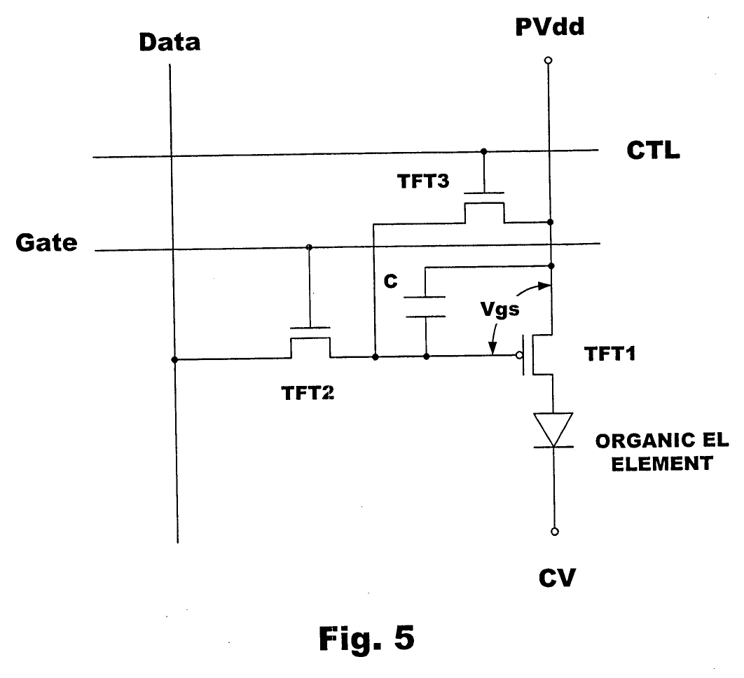

FIG. 5 shows one example of a pixel circuit of this embodiment. As is shown therein, in comparison with the pixel circuit of FIG. 1, a control TFT 3 connected to the control line CTL at the gate is additionally provided between the power supply line PVdd and the gate of the driving TFT 1. In a case where this pixel is selected, when the gate line Gate shifts to the H level while the selection TFT 2 is turned on within a period of one horizontal line, turn-on data is put on the data line Data and written into the retention capacitance C, which allows the organic EL element to turn on. The control line CTL shifts to the H level within a period of one horizontal line after a period of four horizontal lines, and it is turned off as the written data is erased by setting both ends of the retention capacitance C to the PVdd.

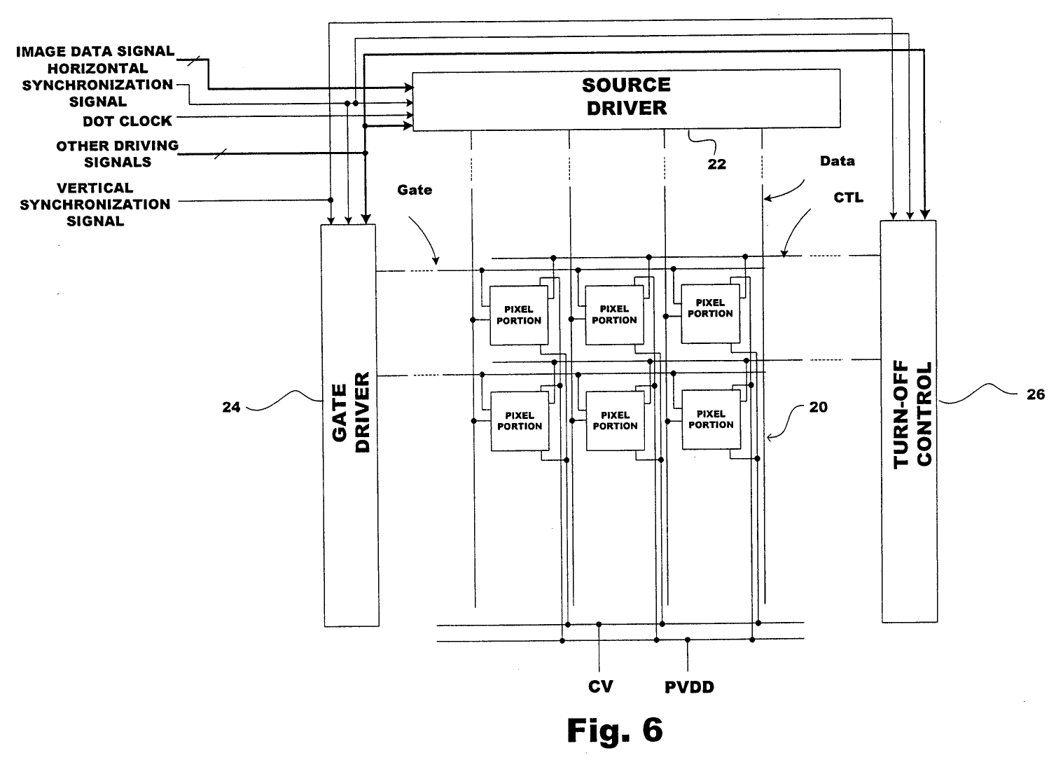

FIG. 6 shows a driver or the like that controls the pixel circuit of FIG. 5. A turn-off control 26 that controls the control line CTL is provided therein. Besides the horizontal and vertical synchronization signals, a driving signal indicating the turn-off timing is supplied to the turn-off control 26. As is shown in FIG. 7, it shifts the control line CTL to the H level a period of four horizontal lines later from the gate line Gate.

In a case where normal display is performed, turning-off is performed frame by frame. More specifically, data from the corresponding data lines is written into pixels in one horizontal line selected by the gate line Gate, and this operation is performed sequentially for the horizontal lines one by one. The writing is performed for all the pixels within one frame period. The turning-off is performed for all the pixels within one frame period. The turning-off of the control line CTL is performed by shifting the control line CTL to the H level during a period of one horizontal line (or a period of a specified number of plural horizontal lines) immediately before the data writing.

Hence, in comparison with the operation for normal display, the measurements of pixel current as described above is characterized by two points as follows: (i) the luminance data supplied to the data line Data is limited to data that turns on one pixel for each specified horizontal line; and (ii) the pixel is turned off after a period of a specified number of horizontal lines (herein, four horizontal lines) since the data was written therein.

Hence, as has been described, by adjusting the driving timing appropriately in the turn-off control 26, the need to change the driving timing for any other driver can be eliminated.

The invention has been described in detail with particular reference to certain preferred embodiments thereof, but it will be understood that variations and modifications can be effected within the spirit and scope of the invention.

### PARTS LIST

1 driving TFT
2 selection TFT
3 control TFT
10 generation circuit
12 CPU
20 display panel
22 source driver
22a data latch
22b D/A converter
24 gate driver
26 turn off control
30 A/D converter
32 memory

1. A method for measuring pixel current in a display device that performs display by writing pixel data into each pixel arranged in a matrix, wherein:
turning on one pixel alone within a screen and then turning off the pixel after measuring the pixel current is performed for a plurality of times within one frame, so as to obtain measurements of pixel current related to a plurality of pixels within one frame period.

2. The method for measuring pixel current in a display device according to claim 1, including:
turning off a pixel after a period of a pre-set number of lines since the data was written therein, and turning on one pixel alone for a period of one or more than one line.

3. The method for measuring pixel current in a display device according to claim 1, wherein:
the display device is an organic EL display device in which an organic EL element is provided to each pixel.

4. A display device that writes pixel data in each of pixels arranged in a matrix to display an image on a screen, comprising:
(a) a turn-on portion that turns on one pixel alone within the screen;
(b) a current measurement portion that measures current flowing in the display device includes:
(i) a turn-off portion that turns off the pixel after pixel current is measured; and
(ii) means for providing measurements of pixel current related to a plurality of pixels within one frame period by measuring current used for display in a period during which one pixel alone is turned on by the turn-on portion in response to the current measurement portion.

5. The display device according to claim 4, wherein:
the display device includes means for turning off the pixel after a period of a pre-set number of lines since the data was written therein; and
means for turning on one pixel alone is turned on for a period of one or more than one line using the turn-off portion.

6. The display device according to claim 4, wherein:
an organic EL element is provided for each pixel.

7. The display device according to claim 4, further including:
a correction data memory that stores correction data to correct pixel data to be supplied to each pixel; and
means for rewriting the correction data in response to the measured pixel current.
